(19) United States
(12) Patent Application Publication
(10) Pub. No.: US 2023/0143105 A1
(43) Pub. Date: May 11, 2023

(54) MOTOR DRIVE DEVICE THAT CALCULATES INSULATION RESISTANCE VALUE OF MOTOR

(71) Applicant: FANUC CORPORATION, Yamanashi (JP)

(72) Inventors: Youichirou Ooi, Minamitsuru-gun, Yamanashi-ken (JP); Koujirou Sakai, Yamanashi (JP)

(21) Appl. No.: 17/918,611

(22) PCT Filed: Jun. 29, 2021
(86) PCT No.: PCT/JP2021/024604

§ 371 Date: Oct. 13, 2022

(30) Foreign Application Priority Data
Jul. 6, 2020 (JP) 2020-116538

(51) Int. Cl. G01R 31/12; G01R 31/34; H02P 23/14; H02P 27/08

(52) U.S. Cl. CPC G01R 31/12; G01R 31/34; H02P 23/14; H02P 27/08; H02P 2201/03

(57) ABSTRACT

A motor drive device 1 is provided with: a converter unit 11 which converts input alternating-current power into direct-current power and outputs the same to a DC link; a DC link capacitor 4; voltage dividing resistors 13-1, 13-2 which are connected in series with one another and which are provided between a positive potential line and a negative potential line of the DC link; a measurement resistor 14 connected between the connecting point of the voltage dividing resistors 13-1 and 13-2 and the positive potential line or the negative potential line of the DC link; a resistance voltage measuring unit 15 for measuring the resistance voltage across the measurement resistor 14; a direct current component extracting unit 16 for extracting the direct current component of the resistance voltage; an alternating current component extracting unit 17 for extracting the alternating current component of the resistance voltage; a DC link potential measuring unit 18 for measuring the positive potential and the negative potential of the DC link; and an insulation resistance value calculating unit 19 for calculating the insulation resistance value of a motor 3 on the basis of the direct current component and the alternating current component of the resistance voltage, and the positive potential and the negative potential of the DC link.

### TECHNICAL FIELD

The present invention relates to a motor drive device for calculating the insulation resistance value of a motor.

### BACKGROUND ART

In a motor drive device that controls driving of a motor in a machine tool, a forging machine, an injection molding machine, an industrial machine, or various robots, a converter unit (rectifying circuit) converts AC power input from an AC power supply into DC power and outputs the DC power to a DC link, and an inverter unit further converts the DC voltage in the DC link into AC power and supplies the AC power as power for driving the motor. The “DC link” refers to a circuit portion that electrically connects the DC output side of the converter unit and the DC input side of the inverter unit to each other, and is also called, e.g., a “DC link portion,” a “direct-current link,” a “direct-current link portion,” or a “direct-current intermediate circuit.”

A motor failure may occur upon insulation deterioration of the motor due to any factor. The insulation deterioration of the motor is detected by measuring an insulation resistance value representing the resistance value between the winding of the motor and the ground.

A motor drive device, for example, is known that includes a rectifying circuit that rectifies an AC voltage supplied from an AC power supply via a first switch into a DC voltage, a power supply unit that uses a capacitor to smooth the DC voltage rectified by the rectifying circuit, an inverter unit that converts the DC voltage smoothed by the power supply unit into an AC voltage by a switching operation of a semiconductor switching element and drives a motor, a current detection unit that measures a current value flowing through a resistor having one end connected to a coil of the motor and the other end connected to one terminal of the capacitor, a voltage detection unit that measures a voltage value between two ends of the capacitor, a second switch that grounds the other terminal of the capacitor, and an insulation resistance detection unit that detects an insulation resistance value of the motor representing a resistance between the coil of the motor and the ground, using two sets of current values and voltage values of the current value and the voltage value measured when an operation of the motor is stopped, the first switch is turned off, and the second switch is set in two states of OFF and ON (see, e.g., PTL 1).

An insulation deterioration detection device for a motor for detecting occurrence of insulation deterioration of a field winding in an active AC motor, for example, is known to include a plurality of detection elements that individually detect an electromagnetic wave when partial discharge has occurred in the field winding of each phase of the AC motor, a ground wire that collectively grounds signals output from the plurality of detection elements, a detection means for extracting a partial discharge signal from the ground wire, a determination means for determining whether the partial discharge falls outside a permissible range, based on a signal output from the detection means, and a warning means for outputting a warning when the determination means determines that the partial discharge falls outside the permissible range (see, e.g., PTL 2).

### CITATIONS LIST

### Patent Literature

[PTL 1] Japanese Unexamined Patent Publication (Kokai) No. 2015-129704
[PTL 2] Japanese Unexamined Patent Publication (Kokai) No. 2002-311080

### SUMMARY OF INVENTION

### Technical Problem

Conventionally, the insulation resistance value of a motor may be preferably measured upon cut-off between an AC power supply and a motor drive device that drives the motor. However, it is troublesome and time-consuming to perform a cut-off operation and a connection operation between the motor drive device and the AC power supply for every measurement of the insulation resistance value of the motor, leading to poor efficiency. It is also conceivable to interpose a circuit breaker between the motor drive device and the AC power supply, but this method is disadvantageous in terms of costs. Therefore, demand has arisen for a technique that can measure the insulation resistance value of a motor at low cost without disconnecting a motor drive device from an AC power supply.

### Solution to Problem

According to one aspect of the present disclosure, a motor drive device includes a converter unit configured to convert alternating-current power input from an alternating-current power supply into direct-current power and output the direct-current power to a direct-current link, a direct-current link capacitor provided in the direct-current link, an inverter unit configured to convert the direct-current power in the direct-current link into alternating-current power for driving a motor and output the alternating-current power, two voltage dividing resistors connected in series with each other and interposed between a positive potential line and a negative potential line forming the direct-current link, the voltage dividing resistors having a connection point between the voltage dividing resistors connected to a winding of the motor, a measurement resistor connected between the connection point between the voltage dividing resistors and one of the positive potential line and the negative potential line of the direct-current link, a resistance voltage measurement unit configured to measure a resistance voltage defined as a potential difference between two ends of the measurement resistor, a direct-current component extraction unit configured to extract a direct-current component from the resistance voltage measured by the resistance voltage measurement unit, an alternating-current component extraction unit configured to extract an alternating-current component from the resistance voltage measured by the resistance voltage measurement unit, a direct-current link potential measurement unit configured to measure a positive potential in the positive potential line of the direct-current link and a negative potential in the negative potential line of the direct-current link, and an insulation resistance value calculation unit configured to calculate an insulation resistance value of the motor, based on the direct-current component extracted by the direct-current component extraction unit, the alternating-current component extracted by the alternating-current component extraction unit, and the positive potential and the negative potential measured by the direct-current link potential measurement unit.

### Advantageous Effects of Invention

According to one aspect of the present disclosure, it is possible to measure the insulation resistance value of a motor at low cost without disconnecting a motor drive device from an AC power supply.

### BRIEF DESCRIPTION OF DRAWINGS

FIG. 1 is a circuit diagram illustrating a motor drive device (first mode) according to one embodiment of the present disclosure.

FIG. 2 is a circuit diagram illustrating a modification of the motor drive device (first mode) according to the embodiment of the present disclosure.

FIG. 3 is a circuit diagram (part 1) illustrating an equivalent circuit used to derive equation (1) in calculation processing by an insulation resistance value calculation unit according to the first mode.

FIG. 4 is a circuit diagram (part 2) illustrating another equivalent circuit used to derive equation (1) in the calculation processing by the insulation resistance value calculation unit according to the first mode.

FIG. 5 is a circuit diagram (part 3) illustrating still another equivalent circuit used to derive equation (1) in the calculation processing by the insulation resistance value calculation unit according to the first mode.

FIG. 6 is a circuit diagram (part 4) illustrating still another equivalent circuit used to derive equation (1) in the calculation processing by the insulation resistance value calculation unit according to the first mode.

FIG. 7 is a circuit diagram (part 5) illustrating still another equivalent circuit used to derive equation (1) in the calculation processing by the insulation resistance value calculation unit according to the first mode.

FIG. 8 is a circuit diagram (part 6) illustrating still another equivalent circuit used to derive equation (1) in the calculation processing by the insulation resistance value calculation unit according to the first mode.

FIG. 9 is a circuit diagram (part 7) illustrating still another equivalent circuit used to derive equation (1) in the calculation processing by the insulation resistance value calculation unit according to the first mode.

FIG. 10 is a circuit diagram (part 8) illustrating still another equivalent circuit used to derive equation (1) in the calculation processing by the insulation resistance value calculation unit according to the first mode.

FIG. 11 is a circuit diagram illustrating a motor drive device (second mode) according to another embodiment of the present disclosure.

FIG. 12 is a circuit diagram (part 1) illustrating an equivalent circuit used to derive equation (11) in calculation processing by an insulation resistance value calculation unit according to the second mode.

FIG. 13 is a circuit diagram (part 2) illustrating another equivalent circuit used to derive equation (11) in the calculation processing by the insulation resistance value calculation unit according to the second mode.

FIG. 14 is a circuit diagram (part 3) illustrating still another equivalent circuit used to derive equation (11) in the calculation processing by the insulation resistance value calculation unit according to the second mode.

FIG. 15 is a circuit diagram (part 4) illustrating still another equivalent circuit used to derive equation (11) in the calculation processing by the insulation resistance value calculation unit according to the second mode.

FIG. 16 is a circuit diagram (part 5) illustrating still another equivalent circuit used to derive equation (11) in the calculation processing by the insulation resistance value calculation unit according to the second mode.

FIG. 17 is a circuit diagram (part 6) illustrating still another equivalent circuit used to derive equation (11) in the calculation processing by the insulation resistance value calculation unit according to the second mode.

FIG. 18 is a circuit diagram (part 7) illustrating still another equivalent circuit used to derive equation (11) in the calculation processing by the insulation resistance value calculation unit according to the second mode.

FIG. 19 is a flowchart illustrating the operation sequence of the motor drive device according to any embodiment of the present disclosure.

FIG. 20 is a graph for explaining simulation results for the positive potential and the negative potential of a DC link when an AC power supply and the motor drive device according to any embodiment of the present disclosure are connected to each other by delta connection.

### DESCRIPTION OF EMBODIMENTS

A motor drive device for calculating the insulation resistance value of a motor will be described below with reference to the drawings. In the drawings, the same or similar reference numerals denote the same or similar members. To facilitate understanding, these drawings use different scales, as appropriate. Further, the modes illustrated in the drawings are merely examples for carrying out the present disclosure, which is not limited to the modes illustrated in the drawings.

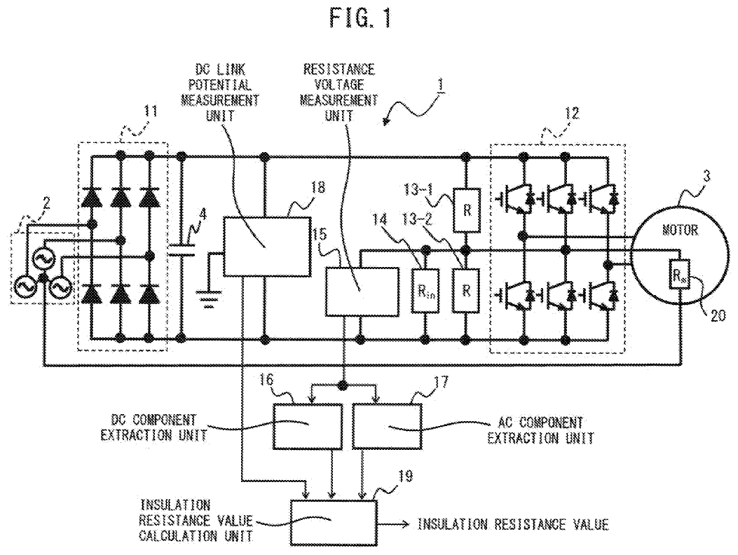

FIG. 1 is a circuit diagram illustrating a motor drive device (first mode) according to one embodiment of the present disclosure. Although details will be described later, one end of a measurement resistor 14 is connected to a negative potential line or a positive potential line of a DC link. The mode in which one end of the measurement resistor 14 is connected to the negative potential line of the DC link will be referred to as a first mode hereinafter, and the mode in which one end of the measurement resistor 14 is connected to the positive potential line of the DC link will be referred to as a second mode hereinafter. The first mode and the second mode are different from each other only in terms of whether one end of the measurement resistor 14 is connected to the negative potential line or the positive potential line of the DC link.

The case where a motor 3 is controlled by a motor drive device 1 connected to an AC power supply 2 will be taken as an example herein. In this embodiment, the type of motor 3 is not particularly limited to any specific type, and may be implemented as, e.g., an induction motor or a synchronous motor. The numbers of phases of the AC power supply 2 and the motor 3 do not particularly limit this embodiment, and a three- or single-phase configuration, for example, may be used. In the example illustrated in FIG. 1, each of the AC power supply 2 and the motor 3 has a three-phase configuration. Examples of the AC power supply 2 may include a 400-V three-phase AC power supply, a 200-V three-phase AC power supply, a 600-V three-phase AC power supply, and a 100-V single-phase AC power supply. Machines equipped with motors 3 include, e.g., a machine tool, a robot, a forging machine, an injection molding machine, an industrial machine, various electrical appliances, an electric train, an automobile, and an aircraft.

The motor drive device 1 according to the embodiment of the present disclosure includes a converter unit 11, a DC link capacitor 4, an inverter unit 12, two voltage dividing resistors 13-1 and 13-2, a measurement resistor 14, a resistance voltage measurement unit 15, a DC component extraction unit 16, an AC component extraction unit 17, a DC link potential measurement unit 18, and an insulation resistance value calculation unit 19, as illustrated in FIG. 1.

The converter unit 11 converts AC power input from the AC power supply 2 into DC power and outputs the DC power to a DC link located on the DC output side. The converter unit 11 is embodied as a three-phase bridge circuit when three-phase AC power is supplied from the AC power supply 2, and is embodied as a single-phase bridge circuit when single-phase AC power is supplied from the AC power supply 2. In the example illustrated in FIG. 1, since the AC power supply 2 is designed as a three-phase AC power supply, the converter unit 11 is embodied as a three-phase bridge circuit. Examples of the converter unit 11 may include a diode rectifier, a 120-degree conduction rectifier, and a PWM switching control rectifier. When, for example, the converter unit 11 serves as a 120-degree conduction rectifier and a PWM switching control rectifier, it is embodied as a bridge circuit of switching elements and diodes connected in antiparallel with the switching elements, and performs bidirectional AC/DC power conversion by ON/OFF control of each switching element in accordance with a drive command received from a host controller (not illustrated). In this case, examples of the switching elements may include FETs, IGBTs, thyristors, GTOs (Gate Turn-OFF thyristors), and transistors, but other types of semiconductor elements may be used.

The inverter unit 12 converts the DC power in the DC link into AC power for driving the motor 3 and outputs the AC power. The inverter unit 12 is formed by a bridge circuit of switching elements and diodes connected in antiparallel with the switching elements. The inverter unit 12 is embodied as a three-phase bridge circuit when the motor 3 is designed as a three-phase AC motor, and is embodied as a single-phase bridge circuit when the motor 3 is designed as a single-phase AC motor. In the example illustrated in FIG. 1, since the motor 3 is designed as a three-phase AC motor, the inverter unit 12 is embodied as a three-phase bridge circuit. The inverter unit 12 is controlled in its power conversion operation by, e.g., the PWM switching control scheme. In other words, the inverter unit 12 converts the DC power in the DC link into AC power for driving the motor 3 and outputs the AC power to the motor 3 in response to a PWM switching command from a host controller (not illustrated), and converts the AC power regenerated by the motor 3 into DC power and returns the DC power to the DC link in motor regeneration.

As in the general motor drive device, the inverter unit 12 is controlled in its power conversion operation by a host controller (not illustrated). In other words, the host controller generates a switching command for controlling the speed, the torque, or the rotor position of the motor 3, based on. e.g., the speed (speed feedback) of the motor 3, the current (current feedback) flowing through the winding of the motor 3, a predetermined torque command, and a motion program for the motor 3. The power conversion operation by the inverter unit 12 is controlled based on the PWM switching command generated by the host controller.

The DC link capacitor 4 is provided in the DC link that connects the DC output side of the converter unit 11 and the DC input side of the inverter unit 12 to each other. The DC link capacitor 4 has a function for suppressing pulsation of the DC output of the converter unit 11, and a function for storing DC power used to generate AC power by the inverter unit 12. Examples of the DC link capacitor 4 may include an electrolytic capacitor and a film capacitor.

The two voltage dividing resistors 13-1 and 13-2 connected in series with each other are interposed between the positive potential line and the negative potential line forming the DC link. A DC link voltage defined as the potential difference between the positive potential in the positive potential line of the DC link and the negative potential in the negative potential line of the DC link is divided by the voltage dividing resistors 13-1 and 13-2. The connection point between the voltage dividing resistors 13-1 and 13-2 is connected to the winding (its input terminal) of the motor 3. In the example illustrated in FIG. 1, the voltage dividing resistors 13-1 and 13-2 are respectively formed by two DC link resistors connected in series with each other between the positive potential line and the negative potential line of the DC link. The DC link resistors are implemented as general resistors. The resistance value of the voltage dividing resistor 13-1 and that of the voltage dividing resistor 13-2 are preferably almost equal to each other, and these resistance values are defined as R in the example illustrated in FIG. 1. However, the resistance value of the voltage dividing resistor 13-1 and that of the voltage dividing resistor 13-2, may take different values. It suffices to measure the resistance values R of the respective voltage dividing resistors 13-1 and 13-2 in advance, or use values specified in specification tables for the voltage dividing resistors 13-1 and 13-2 as these resistance values R.

The measurement resistor 14 is connected between the connection point between the voltage dividing resistors 13-1 and 13-2 and the positive potential line or the negative potential line of the DC link. FIG. 1 illustrates the first mode in which the measurement resistor 14 is connected between the connection point between the voltage dividing resistors 13-1 and 13-2 and the negative potential line of the DC link. The measurement resistor 14 is implemented as a general resistor. The resistance value of the measurement resistor 14 is defined as Rᵢₙ. It suffices to measure the resistance value Rᵢₙ of the measurement resistor 14 in advance, or use a value specified in a specification table for the measurement resistor 14 as this resistance value Rᵢₙ.

The resistance voltage measurement unit 15 measures a resistance voltage defined as the potential difference between the two ends of the measurement resistor 14 in the state in which the power conversion operation by the inverter unit 12 is kept stopped (i.e., the state in which all the switching elements in the inverter unit 12 are kept OFF). A signal associated with the resistance voltage of the measurement resistor 14 measured by the resistance voltage measurement unit 15 is sent to the DC component extraction unit 16 and the AC component extraction unit 17.

The DC component extraction unit 16 extracts a DC component from the resistance voltage measured by the resistance voltage measurement unit 15. The DC component extraction unit 16 is implemented as, e.g., a low-pass filter that removes an AC component from the signal output from the resistance voltage measurement unit 15 and outputs a DC component. A signal associated with the DC component of the resistance voltage extracted by the DC component extraction unit 16 is sent to the insulation resistance value calculation unit 19.

The AC component extraction unit 17 extracts an AC component from the resistance voltage measured by the resistance voltage measurement unit 15. The AC component extraction unit 17 is implemented as, e.g., a high-pass filter that removes a DC component from the signal output from the resistance voltage measurement unit 15 and outputs an AC component. A signal associated with the AC component of the resistance voltage extracted by the AC component extraction unit 17 is sent to the insulation resistance value calculation unit 19.

The DC link potential measurement unit 18 measures the positive potential in the positive potential line of the DC link and the negative potential in the negative potential line of the DC link in the state in which the power conversion operation by the inverter unit 12 is kept stopped (i.e., the state in which all the switching elements in the inverter unit 12 are kept OFF). A signal associated with the positive potential and the negative potential of the DC link measured by the DC link potential measurement unit 18 is sent to the insulation resistance value calculation unit 19.

The insulation resistance value calculation unit 19 calculates an insulation resistance value Rₘ defined as the resistance value of an insulation resistor 20 provided between the winding of the motor 3 and the ground, based on the DC component of the resistance voltage extracted by the DC component extraction unit 16, the AC component of the resistance voltage extracted by the AC component extraction unit 17, and the positive potential and the negative potential of the DC link measured by the DC link potential measurement unit 18. The calculation processing by the insulation resistance value calculation unit 19 will be described in detail later.

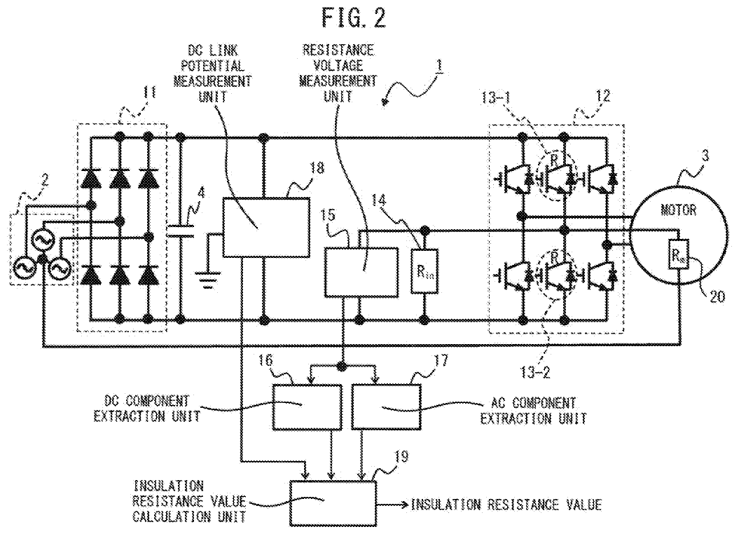

In the embodiment described above with reference to FIG. 1, the voltage dividing resistors 13-1 and 13-2 are respectively formed by two DC link resistors connected in series with each other between the positive potential line and the negative potential line of the DC link. As a modification to this embodiment. OFF resistors for the switching elements in the bridge circuit within the inverter unit 12 may be exploited as the voltage dividing resistors 13-1 and 13-2. FIG. 2 is a circuit diagram illustrating a modification of the motor drive device (first mode) according to the embodiment of the present disclosure. When switching elements respectively provided in an upper arm and a lower arm in the same phase forming the bridge circuit in the inverter unit 12 are turned off, OFF resistors having a predetermined resistance value occur. Since the OFF resistors for the switching elements of the upper arm and the lower arm in the same phase have a function for dividing the DC link voltage, the OFF resistors for the switching elements of the upper arm and the lower arm in the same phase can be used as the voltage dividing resistors 13-1 and 13-2. In this modification, the resistance values of the OFF resistors for the switching elements are defined as R. It suffices to calculate the resistance values R of the OFF resistors for the switching elements, based on the measurement results of the voltages applied to the switching elements in the OFF state.

The calculation processing by the insulation resistance value calculation unit 19 will be described below, separately for the first mode in which one end of the measurement resistor 14 is connected to the negative potential line of the DC link, and the second mode in which one end of the measurement resistor 14 is connected to the positive potential line of the DC link.

The calculation processing by the insulation resistance value calculation unit 19 according to the first mode in which one end of the measurement resistor 14 is connected to the negative potential line of the DC link will be described first.

As described above, FIGS. 1 and 2 illustrate the first mode in which one end of the measurement resistor 14 is connected to the negative potential line of the DC link, i.e., the measurement resistor 14 is connected between the connection point between the voltage dividing resistors 13-1 and 13-2 and the negative potential line of the DC link.

In the first mode illustrated in FIGS. 1 and 2, the insulation resistance value calculation unit 19 calculates the insulation resistance value Rₘ of the motor 3 in accordance with equation (1). In equation (1), Rᵢₙ is the resistance value of the measurement resistor 14, Vₚ is the value of the positive potential of the DC link measured by the DC link potential measurement unit 18 when the power conversion operation by the inverter unit 12 is kept stopped, and Vₙ is the value of the negative potential of the DC link measured by the DC link potential measurement unit 18 when the power conversion operation by the inverter unit 12 is kept stopped. V_{inL} is the value of the DC component of the resistance voltage, when the power conversion operation by the inverter unit 12 is kept stopped, extracted by the DC component extraction unit 16 (low-pass filter), and V_{inH} is the value of the AC component of the resistance voltage, when the power conversion operation by the inverter unit 12 is kept stopped, extracted by the AC component extraction unit 17 (high-pass filter). The value V_{com} is given by (Vₚ+Vₙ)/2, and the value V_{dif} is given by (Vₚ−Vₙ)/2.

$$\begin{matrix}[ Math . 1 ] & \\ {R}_{m} = \frac{{V}_{com} ( {V}_{dif} - {V}_{inL} )}{{V}_{inH} {V}_{dif}} {R}_{in} & ( 1 )\end{matrix}$$

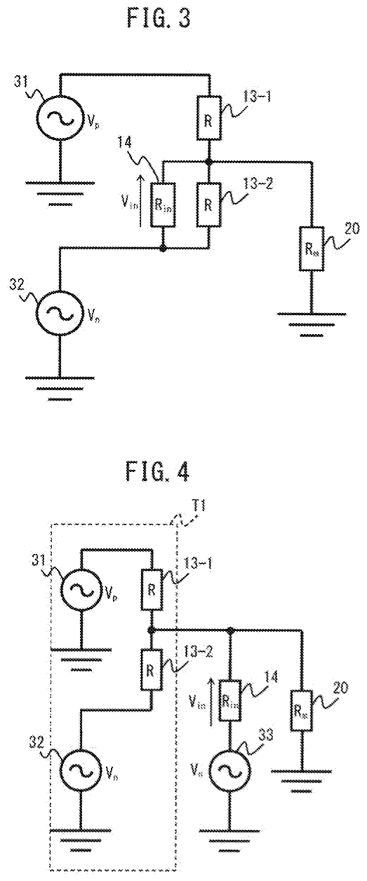

The process of derivation of equation (1) used in the calculation processing by the insulation resistance value calculation unit 19 according to the first mode in which one end of the measurement resistor 14 is connected to the negative potential line of the DC link will be described herein. FIGS. 3 to 10 are circuit diagrams illustrating equivalent circuits used to derive equation (1) in calculation processing by an insulation resistance value calculation unit according to the first mode.

The calculation of the insulation resistance value Rₘ by the insulation resistance value calculation unit 19 uses the data measured by the resistance voltage measurement unit 15 and the DC link potential measurement unit 18 in the state in which the power conversion operation by the inverter unit 12 is kept stopped. In the state in which the power conversion operation by the inverter unit 12 is kept stopped, no circuits associated with the inverter unit 12 appear in FIGS. 3 to 10.

The positive potential Vₚ in the positive potential line of the DC link illustrated in FIGS. 1 and 2 is represented as an equivalent power supply 31 in FIG. 3. Similarly, the negative potential Vₙ in the negative potential line of the DC link illustrated in FIGS. 1 and 2 is represented as an equivalent power supply 32 in FIG. 3. In this case, the voltage dividing resistors 13-1 and 13-2, the measurement resistor 14, and the insulation resistor 20 of the motor 3 illustrated in FIGS. 1 and 2 are connected to the equivalent power supplies 31 and 32 in a configuration as illustrated in FIG. 3. The resistance value of each of the voltage dividing resistors 13-1 and 13-2 is defined as R, the resistance value of the measurement resistor 14 is defined as Rᵢₙ, and the resistance value of the insulation resistor 20 of the motor 3 is defined as Rₘ. The value of the resistance voltage of the measurement resistor 14 measured by the resistance voltage measurement unit 15 is defined as Vᵢₙ.

In the equivalent circuit illustrated in FIG. 3, since the equivalent power supply 32 is connected to one end of the voltage dividing resistor 13-2 and one end of the measurement resistor 14, the equivalent power supply 32 can be divided into two equivalent power supplies 32 and 33 having the same voltage value Vₙ, as illustrated in FIG. 4. In other words, the equivalent power supply 32 is connected to one end of the voltage dividing resistor 13-2, and the equivalent power supply 33 is connected to one end of the measurement resistor 14, as illustrated in FIG. 4.

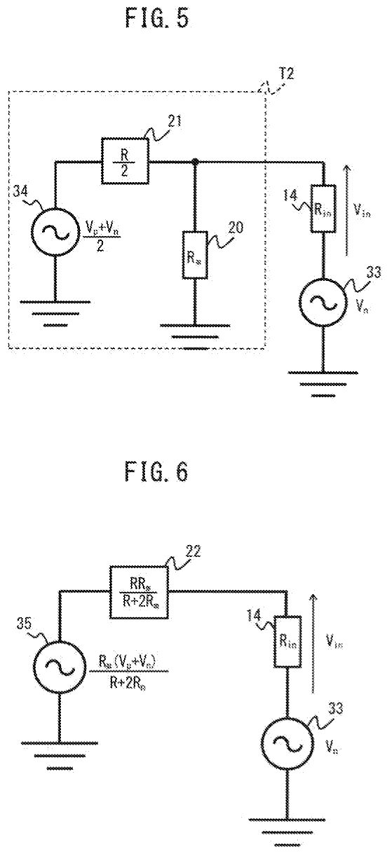

In the equivalent circuit illustrated in FIG. 4, when Thevenin's theorem is applied to a circuit portion T1, an equivalent circuit as illustrated in FIG. 5 is obtained. Referring to FIG. 5, the voltage value V₁ of an equivalent power supply 34 is given by equation (2), and the resistance value of an equivalent resistor 21 is given by R/2.

$$\begin{matrix}[ Math . 2 ] & \\ {V}_{1} = \frac{{V}_{p} + {V}_{n}}{2} & ( 2 )\end{matrix}$$

In the equivalent circuit illustrated in FIG. 5, when Thevenin's theorem is applied to a circuit portion T2, an equivalent circuit as illustrated in FIG. 6 is obtained. Referring to FIG. 6, the voltage value V₂ of an equivalent power supply 35 is given by equation (3), and the resistance value R₁ of an equivalent resistor 22 is given by equation (4).

$$\begin{matrix}[ Math . 3 ] & \\ {V}_{2} = \frac{{R}_{m} ( {V}_{p} + {V}_{n} )}{R + 2 {R}_{m}} & ( 3 )\end{matrix}$$

$$\begin{matrix}[ Math . 4 ] & \\ {R}_{1} = \frac{{RR}_{m}}{R + 2 {R}_{m}} & ( 4 )\end{matrix}$$

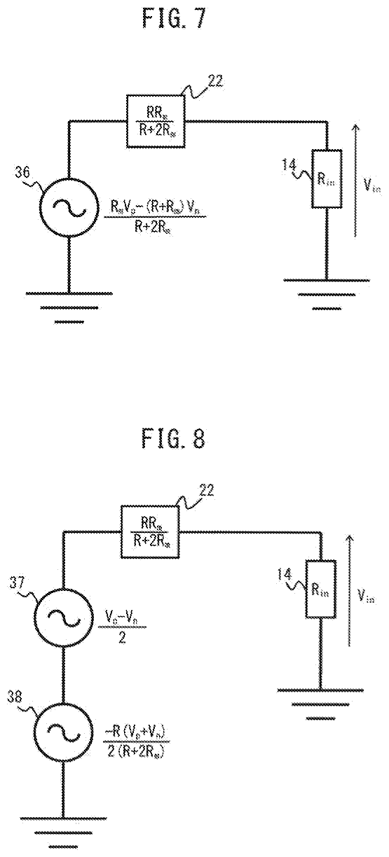

In the equivalent circuit illustrated in FIG. 6, since the equivalent power supplies 33 and 35 are connected in series with each other via the equivalent resistor 22 and the measurement resistor 14, when the equivalent power supplies 33 and 35 are combined into one equivalent power supply, an equivalent power supply 36 as illustrated in FIG. 7 is obtained. Referring to FIG. 7, the voltage value V₃ of the equivalent power supply 36 is given by equation (5).

$$\begin{matrix}[ Math . 5 ] & \\ {V}_{3} = \frac{{R}_{m} {V}_{p} - ( R + {R}_{m} ) {V}_{n}}{R + 2 {R}_{m}} & ( 5 )\end{matrix}$$

In the equivalent circuit illustrated in FIG. 7, when the voltage value V₃ of the equivalent power supply 36 is separated into a differential component and a common-mode component, equivalent power supplies 37 and 38 as illustrated in FIG. 8 are obtained. Referring to FIG. 8, the voltage value V₄ of the equivalent power supply 37 represents a differential component, which is given by equation (6). The voltage value V₅ of the equivalent power supply 38 represents a common-mode component, which is given by equation (7).

$$\begin{matrix}[ Math . 6 ] & \\ {V}_{4} = \frac{{V}_{p} - {V}_{n}}{2} & ( 6 )\end{matrix}$$

$$\begin{matrix}[ Math . 7 ] & \\ {V}_{5} = \frac{- R ( {V}_{p} + {V}_{n} )}{2 ( R + 2 {R}_{m} )} & ( 7 )\end{matrix}$$

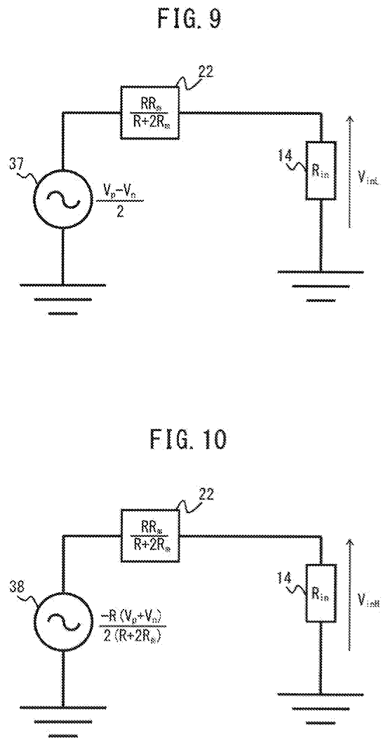

The equivalent circuit illustrated in FIG. 8 can be divided into an equivalent circuit for a DC component illustrated in FIG. 9 and an equivalent circuit for an AC component illustrated in FIG. 10.

In the equivalent circuit of the DC component, the equivalent resistor 22 and the measurement resistor 14 are connected to the equivalent power supply 37 containing the differential component V₄, as illustrated in FIG. 9. The voltage component V_{inL} applied to the measurement resistor 14 is calculated using Ohm's law, as equation (8). In equation (8), V_{com} is substituted for (Vₚ+Vₙ)/2 representing a signal component containing no DC component, and V_{dif} is substituted for (Vₚ−Vₙ)/2 representing a signal component containing a DC component. The voltage component V_{inL} corresponds to a DC component obtained by removing, by the DC component extraction unit 16 (low-pass filter), an AC component from the resistance voltage of the measurement resistor 14 measured by the resistance voltage measurement unit 15.

$$\begin{matrix}[ Math . 8 ] & \\ {V}_{inL} = \frac{{R}_{in} ( R + 2 {R}_{in} )}{{R}_{m} R + {R}_{in} ( R + 2 {R}_{m} )} {V}_{dif} & ( 8 )\end{matrix}$$

In the equivalent circuit of the AC component, the equivalent resistor 22 and the measurement resistor 14 are connected to the equivalent power supply 38 containing the common-mode component V₅, as illustrated in FIG. 10. The voltage component V_{inH} applied to the measurement resistor 14 is calculated using Ohm's law, as equation (9). In equation (9), V_{com} is substituted for (Vₚ+Vₙ)/2 representing a signal component containing no DC component, and V_{dif} is substituted for (Vₚ−Vₙ)/2 representing a signal component containing a DC component. The voltage component V_{inH} corresponds to an AC component obtained by removing, by the AC component extraction unit 17 (high-pass filter), a DC component from the resistance voltage of the measurement resistor 14 measured by the resistance voltage measurement unit 15.

$$\begin{matrix}[ Math . 9 ] & \\ {V}_{inH} = \frac{- {RR}_{in}}{{R}_{m} R + {R}_{in} ( R + 2 {R}_{m} )} {V}_{com} & ( 9 )\end{matrix}$$

Solving simultaneous equations defined by equations (8) and (9) for the insulation resistance value Rₘ yields equation (1) for calculating the insulation resistance value Rₘ. In the first mode in which one end of the measurement resistor 14 is connected to the negative potential line of the DC link, the insulation resistance value calculation unit 19 calculates the insulation resistance value Rₘ of the motor 3 in accordance with equation (1). In equation (1), the value V_{com} is expressed as (Vₚ+Vₙ)/2, and the value V_{dif} is expressed as (Vₚ−Vₙ)/2. Vₚ is the positive potential in the positive potential line of the IC link measured by the DC link potential measurement unit 18 when the power conversion operation by the inverter unit 12 is kept stopped, Vₙ is the negative potential in the negative potential line of the DC link measured by the DC link potential measurement unit 18 when the power conversion operation by the inverter unit 12 is kept stopped. The DC component V_{inL} is obtained by removing, by the DC component extraction unit 16 (low-pass filter), an AC component from the resistance voltage of the measurement resistor 14 measured by the resistance voltage measurement unit 15 when the power conversion operation by the inverter unit 12 is kept stopped. The AC component V_{inH} is obtained by removing, by the AC component extraction unit 17 (high-pass filter), a DC component from the resistance voltage of the measurement resistor 14 measured by the resistance voltage measurement unit 15 when the power conversion operation by the inverter unit 12 is kept stopped. It suffices to measure the resistance value Rᵢₙ of the measurement resistor 14 in advance, or use a value specified in a specification table as this resistance value Rᵢₙ. The resistance value R of each of the voltage dividing resistors 13-1 and 13-2 can be calculated by solving simultaneous equations defined by equations (8) and (9). In other words, “calculating the insulation resistance value Rₘ of the motor 3 in accordance with equation (1)” means “calculating the insulation resistance value Rₘ of the motor 3, based on the DC component V_{inL} of the resistance voltage extracted by the DC component extraction unit 16, the AC component V_{inH} of the resistance voltage extracted by the AC component extraction unit 17, and the positive potential Vₚ and the negative potential Vₙ of the DC link measured by the DC link potential measurement unit 18.”

In the first mode, the value V_{com} and the AC component V_{inH}, and the value V_{dif} and the DC component V_{inL} may be measured after conversion into a direct current through a rectifying circuit. In this case, for example, the AC component V_{inH} of the resistance voltage extracted by the AC component extraction unit 17 is rectified, the absolute value of the rectified component is obtained, and the insulation resistance value Rₘ of the motor 3 is calculated in accordance with equation (10) based on this value. Alternatively, for example, the AC component V_{inH} of the resistance voltage extracted by the AC component extraction unit 17 is rectified, and the absolute value of the rectified component is obtained, while the DC component V_{inL} of the resistance voltage extracted by the DC component extraction unit 16 is rectified, and the absolute value of the rectified component is obtained, and the insulation resistance value Rₘ of the motor 3 is calculated in accordance with equation (10) based on these values. Since the absolute values of the AC component V_{inH} in equation (9) and the DC component V_{inL} in equation (8) are taken, some signs in equation (10) are different from those in equation (1).

$$\begin{matrix}[ Math . 10 ] & \\ {R}_{m} = \frac{{V}_{com} ( {V}_{dif} + {V}_{inL} )}{{V}_{inH} {V}_{dif}} {R}_{in} & ( 10 )\end{matrix}$$

The calculation processing by the insulation resistance value calculation unit 19 according to the second mode in which one end of the measurement resistor 14 is connected to the positive potential line of the DC link will be described below.

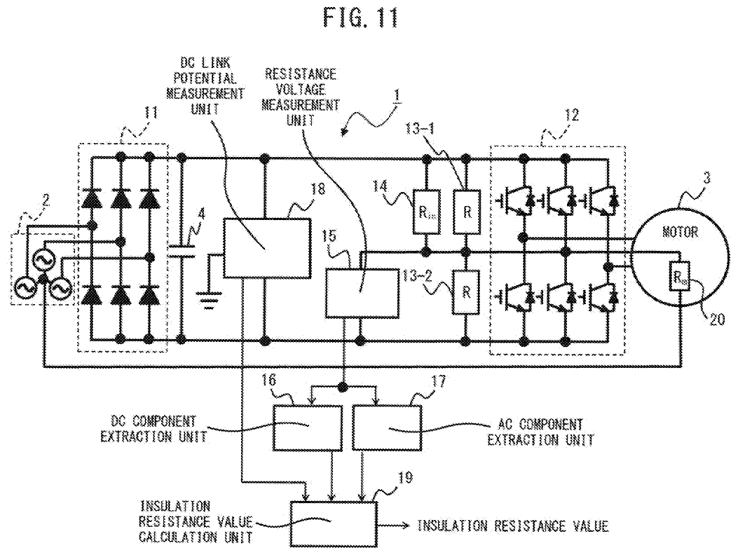

FIG. 11 is a circuit diagram illustrating a motor drive device (second mode) according to another embodiment of the present disclosure. In the second mode, the measurement resistor 14 is connected between the connection point between the voltage dividing resistors 13-1 and 13-2 and the positive potential line of the DC link. Since circuit components other than those constituting this configuration are the same as the circuit components illustrated in FIG. 1, the same reference numerals denote the same circuit components, and a detailed description thereof will not be given. As in the first mode, in the second mode, OFF resistors for the switching elements in the bridge circuit within the inverter unit 12 may be utilized as the voltage dividing resistors 13-1 and 13-2.

In the second mode illustrated in FIG. 11, the insulation resistance value calculation unit 19 calculates the insulation resistance value Rₘ of the motor 3 in accordance with equation (11). In equation (11). Rᵢₙ is the resistance value of the measurement resistor 14, Vₚ is the value of the positive potential of the DC link measured by the DC link potential measurement unit 18 when the power conversion operation by the inverter unit 12 is kept stopped, and Vₙ is the value of the negative potential of the DC link measured by the DC link potential measurement unit 18 when the power conversion operation by the inverter unit 12 is kept stopped. V_{inL} is the value of the DC component of the resistance voltage, when the power conversion operation by the inverter unit 12 is kept stopped, extracted by the DC component extraction unit 16 (low-pass filter), and V_{inH} is the value of the AC component of the resistance voltage, when the power conversion operation by the inverter unit 12 is kept stopped, extracted by the AC component extraction unit 17 (high-pass filter). The value V_{com} is given by (Vₚ+Vₙ)/2, and the value V_{dif} is given by (Vₚ−Vₙ)/2.

$$\begin{matrix}[ Math . 11 ] & \\ {R}_{m} = - \frac{{V}_{com} ( {V}_{dif} + {V}_{inL} )}{{V}_{inH} {V}_{dif}} {R}_{in} & ( 11 )\end{matrix}$$

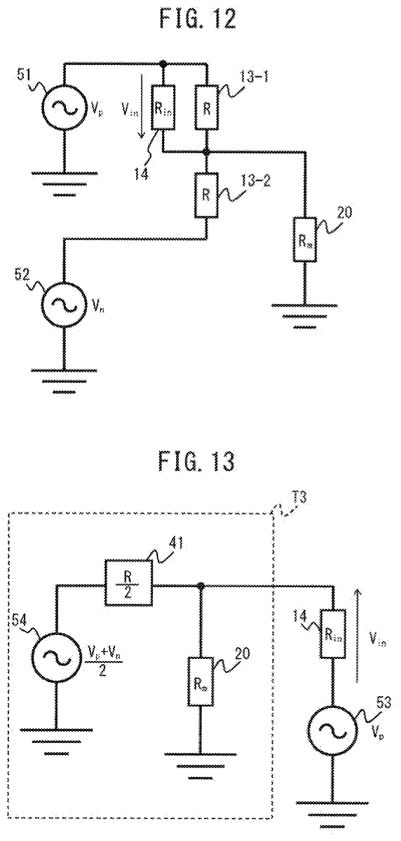

The process of derivation of equation (11) used in the calculation processing by the insulation resistance value calculation unit 19 according to the second mode in which one end of the measurement resistor 14 is connected to the positive potential line of the DC link will be described herein. FIGS. 12 to 18 are circuit diagrams illustrating equivalent circuits used to derive equation (11) in calculation processing by an insulation resistance value calculation unit according to the second mode.

The calculation of the insulation resistance value Rₘ by the insulation resistance value calculation unit 19 uses the data measured by the resistance voltage measurement unit 15 and the DC link potential measurement unit 18 in the state in which the power conversion operation by the inverter unit 12 is kept stopped. In the state in which the power conversion operation by the inverter unit 12 is kept stopped, no circuits associated with the inverter unit 12 appear in FIGS. 12 to 18.

The positive potential Vₚ in the positive potential line of the DC link illustrated in FIG. 11 is represented as an equivalent power supply 51 in FIG. 12. Similarly, the negative potential Vₙ in the negative potential line of the DC link illustrated in FIG. 3 is represented as an equivalent power supply 52 in FIG. 12. In this case, the voltage dividing resistors 13-1 and 13-2, the measurement resistor 14, and the insulation resistor 20 of the motor 3 illustrated in FIG. 11 are connected to the equivalent power supplies 51 and 52 in a configuration as illustrated in FIG. 12. The resistance value of each of the voltage dividing resistors 13-1 and 13-2 is defined as R, the resistance value of the measurement resistor 14 is defined as Rᵢₙ, and the resistance value of the insulation resistor 20 of the motor 3 is defined as Rₘ. The value of the resistance voltage of the measurement resistor 14 measured by the resistance voltage measurement unit 15 is defined as Vᵢₙ.

In the equivalent circuit illustrated in FIG. 12, when Thevenin's theorem is applied to the equivalent power supplies 51 and 52 and the voltage dividing resistors 13-1 and 13-2, an equivalent circuit as illustrated in FIG. 13 is obtained. Referring to FIG. 5, the voltage value V₆ of an equivalent power supply 54 is given by equation (12), and the resistance value of an equivalent resistor 41 is given by R/2.

$$\begin{matrix}[ Math . 12 ] & \\ {V}_{6} = \frac{{V}_{p} + {V}_{n}}{2} & ( 12 )\end{matrix}$$

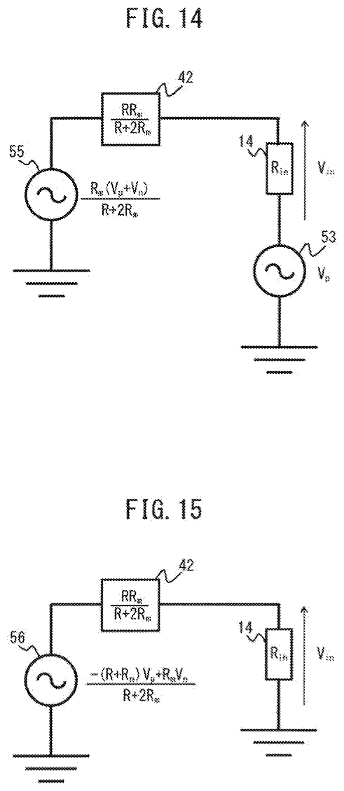

In the equivalent circuit illustrated in FIG. 13, when Thevenin's theorem is applied to a circuit portion T3, an equivalent circuit as illustrated in FIG. 14 is obtained. Referring to FIG. 14, the voltage value V₇ of an equivalent power supply 55 is given by equation (13), and the resistance value R₂ of an equivalent resistor 42 is given by equation (14).

$$\begin{matrix}[ Math . 13 ] & \\ {V}_{7} = \frac{{R}_{m} ( {V}_{p} + {V}_{n} )}{R + 2 {R}_{m}} & ( 13 )\end{matrix}$$

$$\begin{matrix}[ Math . 14 ] & \\ {R}_{2} = \frac{{RR}_{m}}{R + 2 {R}_{m}} & ( 14 )\end{matrix}$$

In the equivalent circuit illustrated in FIG. 14, since an equivalent power supply 53 and the equivalent power supply 55 are connected in series with each other via the equivalent resistor 42 and the measurement resistor 14, when the equivalent power supplies 53 and 55 are combined into one equivalent power supply, an equivalent power supply 56 as illustrated in FIG. 15 is obtained. Referring to FIG. 15, the voltage value V₈ of the equivalent power supply 56 is given by equation (15).

$$\begin{matrix}[ Math . 15 ] & \\ {V}_{8} = \frac{- ( R + {R}_{m} ) {V}_{p} + {R}_{m} {V}_{n}}{R + 2 {R}_{m}} & ( 15 )\end{matrix}$$

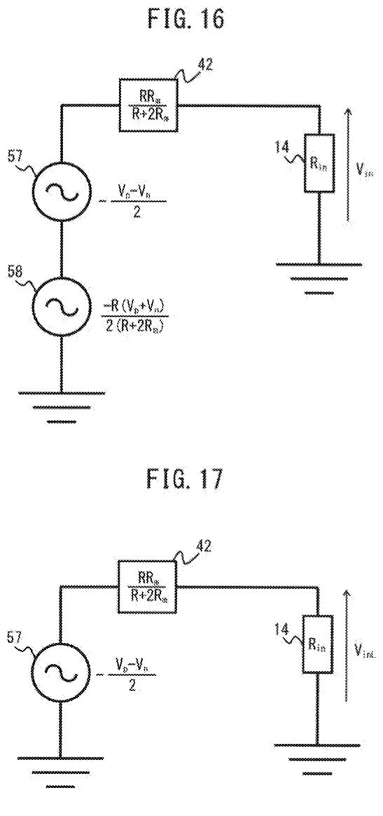

In the equivalent circuit illustrated in FIG. 15, when the voltage value V₈ of the equivalent power supply 56 is separated into a differential component and a common-mode component, equivalent power supplies 57 and 58 as illustrated in FIG. 16 are obtained. Referring to FIG. 16, the voltage value V₉ of the equivalent power supply 57 represents a differential component, which is given by equation (16). The voltage value V₁₀ of the equivalent power supply 58 represents a common-mode component, which is given by equation (17).

$$\begin{matrix}[ Math . 16 ] & \\ {V}_{9} = - \frac{{V}_{p} - {V}_{n}}{2} & ( 16 )\end{matrix}$$

$$\begin{matrix}[ Math . 17 ] & \\ {V}_{10} = \frac{- R ( {V}_{p} + {V}_{n} )}{2 ( R + 2 {R}_{m} )} & ( 17 )\end{matrix}$$

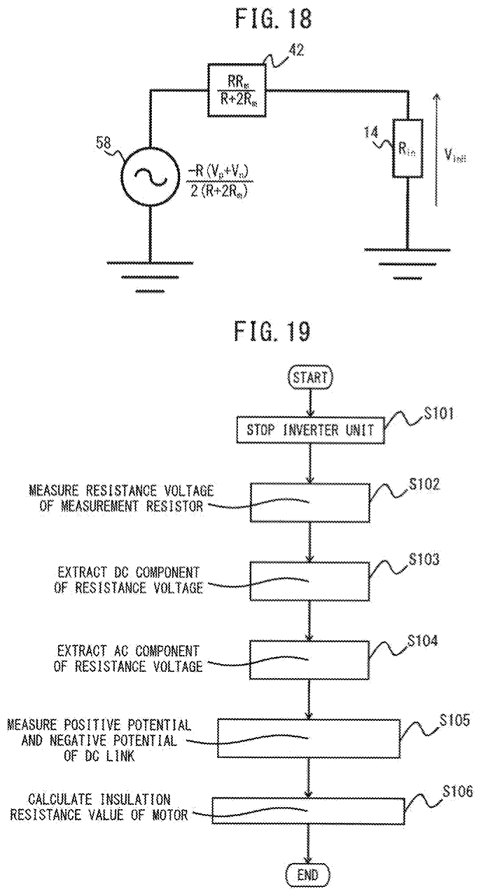

The equivalent circuit illustrated in FIG. 16 can be divided into an equivalent circuit for a DC component illustrated in FIG. 17 and an equivalent circuit for an AC component illustrated in FIG. 18.

In the equivalent circuit of the DC component, the equivalent resistor 42 and the measurement resistor 14 are connected to the equivalent power supply 57 containing the differential component V₉, as illustrated in FIG. 17. The voltage component V_{inL} applied to the measurement resistor 14 is calculated using Ohm's law, as equation (18). In equation (18), V_{com} is substituted for (Vₚ+V_{B})/2 representing a signal component containing no DC component, and V_{dif} is substituted for (Vₚ−Vₙ)/2 representing a signal component containing a DC component. The voltage component V_{inL} corresponds to a DC component obtained by removing, by the DC component extraction unit 16 (low-pass filter), an AC component from the resistance voltage of the measurement resistor 14 measured by the resistance voltage measurement unit 15.

$$\begin{matrix}[ Math . 18 ] & \\ {V}_{inL} = \frac{- {R}_{in} ( R + 2 {R}_{in} )}{{R}_{m} R + {R}_{in} ( R + 2 {R}_{m} )} {V}_{dif} & ( 18 )\end{matrix}$$

In the equivalent circuit of the AC component, the equivalent resistor 42 and the measurement resistor 14 are connected to the equivalent power supply 58 containing the common-mode component V₁₀, as illustrated in FIG. 18. The voltage component V_{inH} applied to the measurement resistor 14 is calculated using Ohm's law, as equation (19). In equation (19), V_{com} is substituted for (Vₚ+Vₙ)/2 representing a signal component containing no DC component, and V_{dif} is substituted for (Vₚ−Vₙ)/2 representing a signal component containing a DC component. The voltage component V_{inH} corresponds to an AC component obtained by removing, by the AC component extraction unit 17 (high-pass filter), a DC component from the resistance voltage of the measurement resistor 14 measured by the resistance voltage measurement unit 15.

$$\begin{matrix}[ Math . 19 ] & \\ {V}_{inH} = \frac{- {RR}_{in}}{{R}_{m} R + {R}_{in} ( R + 2 {R}_{m} )} {V}_{com} & ( 19 )\end{matrix}$$

Solving simultaneous equations defined by equations (18) and (19) for the insulation resistance value Rₘ yields equation (11) for calculating the insulation resistance value Rₘ. In the second mode in which one end of the measurement resistor 14 is connected to the positive potential line of the DC link, the insulation resistance value calculation unit 19 calculates the insulation resistance value Rₘ of the motor 3 in accordance with equation (11). In equation (11), the value V_{com} is expressed as (Vₚ+Vₙ)/2, and the value V_{dif} is expressed as (Vₚ−Vₙ)/2. Vₚ is the positive potential in the positive potential line of the DC link measured by the DC link potential measurement unit 18 when the power conversion operation by the inverter unit 12 is kept stopped. Vₙ is the negative potential in the negative potential line of the DC link measured by the DC link potential measurement unit 18 when the power conversion operation by the inverter unit 12 is kept stopped. The DC component V_{inL} is obtained by removing, by the DC component extraction unit 16 (low-pass filter), an AC component from the resistance voltage of the measurement resistor 14 measured by the resistance voltage measurement unit 15 when the power conversion operation by the inverter unit 12 is kept stopped. The AC component V_{inH} is obtained by removing, by the AC component extraction unit 17 (high-pass filter), a DC component from the resistance voltage of the measurement resistor 14 measured by the resistance voltage measurement unit 15 when the power conversion operation by the inverter unit 12 is kept stopped. It suffices to measure the resistance value Rᵢₙ of the measurement resistor 14 in advance, or use a value specified in a specification table as this resistance value Rᵢₙ. The resistance value R of each of the voltage dividing resistors 13-1 and 13-2 can be calculated by solving simultaneous equations defined by equations (18) and (19). In other words, “calculating the insulation resistance value Rₘ of the motor 3 in accordance with equation (11)” means “calculating the insulation resistance value Rₘ of the motor 3, based on the DC component V_{inL} of the resistance voltage extracted by the DC component extraction unit 16, the AC component V_{inH} of the resistance voltage extracted by the AC component extraction unit 17, and the positive potential Vₚ and the negative potential Vₙ of the DC link measured by the DC link potential measurement unit 18.”

In the second mode, the value V_{com} and the AC component V_{inH}, and the value V_{dif} and the DC component V_{inL} may be measured after conversion into a direct current through a rectifying circuit. In this case, for example, the AC component V_{inH} of the resistance voltage extracted by the AC component extraction unit 17 is rectified, the absolute value of the rectified component is obtained, the AC component V_{inH} of the resistance voltage extracted in accordance with equation (20) based on this value is rectified, and the absolute value of the rectified component is obtained, while the DC component V_{inL} of the resistance voltage extracted by the DC component extraction unit 16 is rectified, and the absolute value of the rectified component is obtained, and the insulation resistance value Rₘ of the motor 3 is calculated in accordance with equation (20) based on these values. Since the absolute values of the AC component V_{inH} in equation (19) and the DC component V_{inL} in equation (18) are taken, some signs in equation (20) are different from those in equation (11).

$$\begin{matrix}[ Math . 20 ] & \\ {R}_{m} = \frac{{V}_{com} ( {V}_{dif} + {V}_{inL} )}{{V}_{inH} {V}_{dif}} {R}_{in} & ( 20 )\end{matrix}$$

As described above, in both the first mode and the second mode, the measurement processing by the resistance voltage measurement unit 15 and the measurement processing by the IX link potential measurement unit 18 are performed in the state in which the power conversion operation by the inverter unit 12 is kept stopped (i.e., the state in which all the switching elements in the inverter unit 12 are kept OFF), and the insulation resistance value calculation unit 19 calculates the insulation resistance value Rₘ, based on the data measured at this time. In other words, according to one embodiment of the present disclosure, the insulation resistance value Rₘ of the motor 3 can be measured by operating the resistance voltage measurement unit 15, the DC component extraction unit 16, the AC component extraction unit 17, the DC link potential measurement unit 18, and the insulation resistance value calculation unit 19 in the state in which the power conversion operation by the inverter unit 12 is kept stopped. Hence, unlike the conventional techniques, the motor drive device 1 may not be preferably disconnected from the AC power supply 2 in measuring the insulation resistance value Rₘ of the motor 3. In addition, no circuit breaker may be preferably interposed between the motor drive device 1 and the AC power supply 2 to measure the insulation resistance value Rₘ of the motor 3, resulting in low cost. Even when no circuit breaker is interposed between the motor drive device 1 and the AC power supply 2, the insulation resistance value Rₘ of the motor 3 can be measured.

The insulation resistance value Rₘ calculated by the insulation resistance value calculation unit 19 may be displayed on, e.g., a display unit (not illustrated). With this operation, the operator can quickly and easily know the insulation resistance value Rₘ of the motor 3.

A determination unit (not illustrated) that performs insulation deterioration determination of the motor 3 by comparing the insulation resistance value Rₘ calculated by the insulation resistance value calculation unit 19 with a threshold serving as a criterion for determining insulation deterioration may be provided, and information indicating that “insulation deterioration has occurred in the motor 3” may be displayed on the display unit when the determination unit determines that the insulation resistance value Rₘ has exceeded the threshold. Examples of the display unit may include an independent display device, a display device attached to the motor drive device 1, and display devices attached to a personal computer and a portable terminal. Alternatively, the operator may be notified that “insulation deterioration has occurred in the motor 3” by an acoustic device that emits a sound like that produced by, e.g., a voice, a loudspeaker, a buzzer, or a chime, in addition to or instead of such a display unit. With this operation, the operator can quickly and easily understand that insulation deterioration has occurred in the motor 3. Hence, the operator can easily carry out a remedial measure such as replacement or repairing of the motor 3.

The DC component extraction unit 16, the AC component extraction unit 17, the insulation resistance value calculation unit 19, and the host controller may be implemented as a combination of an analog circuit and an arithmetic processing unit, or may be implemented solely as an arithmetic processing unit, or may be implemented solely as an analog circuit. When, for example, the DC component extraction unit 16, the AC component extraction unit 17, the insulation resistance value calculation unit 19, and the host controller are constructed in software program form, the function of each of the DC component extraction unit 16, the AC component extraction unit 17, the insulation resistance value calculation unit 19, and the host controller can be implemented by running the arithmetic processing unit in accordance with the software program. Alternatively, the DC component extraction unit 16, the AC component extraction unit 17, the insulation resistance value calculation unit 19, and the host controller may be implemented as a semiconductor integrated circuit in which a software program for implementing the function of each unit is written. As another alternative, the DC component extraction unit 16, the AC component extraction unit 17, the insulation resistance value calculation unit 19, and the host controller may be implemented as a recording medium in which a software program for implementing the function of each unit is written. The DC component extraction unit 16, the AC component extraction unit 17, the insulation resistance value calculation unit 19, and the host controller, for example, may be provided in a numerical controller for a machine tool, or may be provided in a robot controller that controls a robot.

The resistance voltage measurement unit 15 and the DC link potential measurement unit 18 may be implemented as a combination of an analog circuit and an arithmetic processing unit, or may be implemented solely as an arithmetic processing unit, or may be implemented solely as an analog circuit. As the resistance voltage measurement unit 15 and the DC link potential measurement unit 18, measurement units generally provided in the motor drive device 1 may be exploited. However, calculation of the insulation resistance value Rₘ by the insulation resistance value calculation unit 19, uses the data measured by the resistance voltage measurement unit 15 and the DC link potential measurement unit 18 in the state in which the power conversion operation by the inverter unit 12 is kept stopped.

FIG. 19 is a flowchart illustrating the operation sequence of the motor drive device according to any embodiment of the present disclosure. The flowchart illustrated in FIG. 19 is applicable to the motor drive devices 1 in both the first mode and the second mode.

In measuring an insulation resistance value Rₘ of the motor 3, first, in step S101, a host controller (not illustrated) turns off all the switching elements in the inverter unit 12 to stop the power conversion operation by the inverter unit 12.

In step S102, the resistance voltage measurement unit 15 measures a resistance voltage Vᵢₙ defined as the potential difference between the two ends of the measurement resistor 14. A signal associated with the resistance voltage Vᵢₙ of the measurement resistor 14 measured by the resistance voltage measurement unit 15 is sent to the DC component extraction unit 16 and the AC component extraction unit 17.

In step S103, the DC component extraction unit 16 extracts a DC component V_{inL} from the resistance voltage Vᵢₙ measured by the resistance voltage measurement unit 15. A signal associated with the DC component V_{inL} of the resistance voltage extracted by the DC component extraction unit 16 is sent to the insulation resistance value calculation unit 19.

In step S104, the AC component extraction unit 17 extracts an AC component V_{inH} from the resistance voltage Vᵢₙ measured by the resistance voltage measurement unit 15. A signal associated with the AC component V_{inH} of the resistance voltage extracted by the AC component extraction unit 17 is sent to the insulation resistance value calculation unit 19.

The process in step S103 and the process in step S104 may be performed in reverse order.

In step S105, the DC link potential measurement unit 18 measures a positive potential Vₚ in the positive potential line of the DC link and a negative potential Vₙ in the negative potential line of the DC link. A signal associated with the positive potential Vₚ and the negative potential Vₙ of the DC link measured by the DC link potential measurement unit 18 is sent to the insulation resistance value calculation unit 19.

The series of processes in steps S102 to S104 and the process in step S105 may be performed in reverse order.

In step S106, the insulation resistance value calculation unit 19 calculates an insulation resistance value Rₘ of the motor 3, based on the DC component V_{inL} of the resistance voltage extracted by the DC component extraction unit 16, the AC component V_{inH} of the resistance voltage extracted by the AC component extraction unit 17, and the positive potential Vₚ and the negative potential Vₙ of the DC link measured by the DC link potential measurement unit 18. In the first mode in which one end of the measurement resistor 14 is connected to the negative potential line of the DC link, the insulation resistance value calculation unit 19 calculates the insulation resistance value Rₘ of the motor 3 in accordance with equation (1). In the second mode in which one end of the measurement resistor 14 is connected to the positive potential line of the DC link, the insulation resistance value calculation unit 19 calculates the insulation resistance value Rₘ of the motor 3 in accordance with equation (11).

After step S106, for example, the insulation resistance value Rₘ calculated by the insulation resistance value calculation unit 19 may be displayed on a display unit (not illustrated). As another example, a determination unit (not illustrated) that performs insulation deterioration determination of the motor 3 by comparing the insulation resistance value Rₘ calculated by the insulation resistance value calculation unit 19 with a threshold serving as a criterion for determining insulation deterioration may be provided, and information indicating that “insulation deterioration has occurred in the motor 3” may be displayed on the display unit when the determination unit determines that the insulation resistance value Rₘ has exceeded the threshold. As still another example, the operator may be notified that “insulation deterioration has occurred in the motor 3” by an acoustic device that emits a sound like that produced by, e.g., a voice, a loudspeaker, a buzzer, or a chime, in addition to or instead of such a display unit.

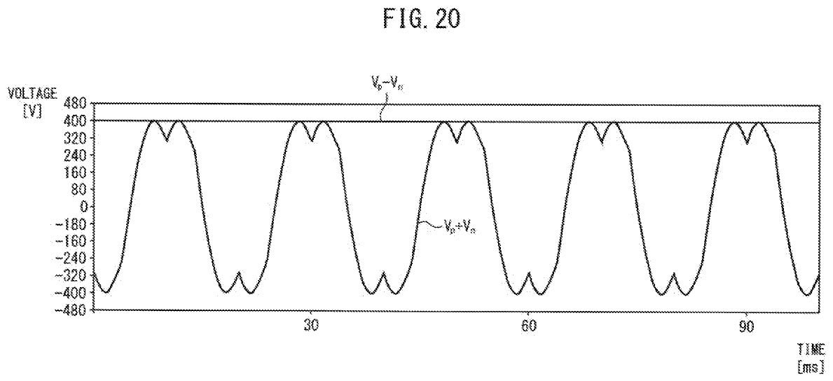

FIG. 20 is a graph for explaining simulation results for the positive potential and the negative potential of a DC link when an AC power supply and the motor drive device according to any embodiment of the present disclosure are connected to each other by delta connection. As presented in equations (1) and (11), the value V_{com} expressed as (Vₚ+Vₙ)/2, and the value V_{dif} expressed as (Vₚ−Vₙ)/2 are used to calculate the insulation resistance value Rₘ. FIG. 20 reveals that the difference “Vₚ−Vₙ” between the positive potential Vₚ and the negative potential Vₙ stays constant and therefore functions as a DC component, and the sum “Vₚ+Vₙ” of the positive potential Vₚ and the negative potential Vₙ is AC waveform and therefore functions as an AC component.

### REFERENCE SIGNS LIST

1 Motor drive device
2 AC power supply
3 Motor
4 DC link capacitor
11 Converter unit
12 Inverter unit
13-1, 13-2 Voltage dividing resistor
14 Measurement resistor
15 Resistance voltage measurement unit
16 DC component extraction unit
17 AC component extraction unit
18 DC link potential measurement unit
19 Insulation resistance value calculation unit
20 Insulation resistor for motor
21, 22 Equivalent resistor
31, 32, 33, 34, 35, 36, 37, 38 Equivalent power supply
41, 42 Equivalent resistor
51, 52, 53, 54, 55, 56, 57, 58 Equivalent power supply

1. A motor drive device comprising:
a converter unit configured to convert alternating-current power input from an alternating-current power supply into direct-current power and output the direct-current power to a direct-current link;
a direct-current link capacitor provided in the direct-current link;
an inverter unit configured to convert the direct-current power in the direct-current link into alternating-current power for driving a motor and output the alternating-current power;
two voltage dividing resistors connected in series with each other and interposed between a positive potential line and a negative potential line forming the direct-current link, the voltage dividing resistors having a connection point between the voltage dividing resistors connected to a winding of the motor;
a measurement resistor connected between the connection point between the voltage dividing resistors and one of the positive potential line and the negative potential line of the direct-current link;
a resistance voltage measurement unit configured to measure a resistance voltage defined as a potential difference between two ends of the measurement resistor;
a direct-current component extraction unit configured to extract a direct-current component from the resistance voltage measured by the resistance voltage measurement unit;
an alternating-current component extraction unit configured to extract an alternating-current component from the resistance voltage measured by the resistance voltage measurement unit;
a direct-current link potential measurement unit configured to measure a positive potential in the positive potential line of the direct-current link and a negative potential in the negative potential line of the direct-current link; and
an insulation resistance value calculation unit configured to calculate an insulation resistance value of the motor, based on the direct-current component extracted by the direct-current component extraction unit, the alternating-current component extracted by the alternating-current component extraction unit, and the positive potential and the negative potential measured by the direct-current link potential measurement unit.

2. The motor drive device according to claim 1, wherein
the measurement resistor is connected between the connection point between the voltage dividing resistors and the negative potential line of the direct-current link, and
the insulation resistance value calculation unit calculates an insulation resistance value Rₘ of the motor in accordance with:
$$\begin{matrix}[ Math . 1 ] & \\ {R}_{m} = \frac{{V}_{com} ( {V}_{dif} - {V}_{inL} )}{{V}_{inH} {V}_{dif}} {R}_{in} & \end{matrix}$$
where Rᵢₙ is a resistance value of the measurement resistor, Vₚ is a value of the positive potential measured by the direct-current link potential measurement unit, Vₙ is a value of the negative potential measured by the direct-current link potential measurement unit, V_{inL} is a value of the direct-current component extracted by the direct-current component extraction unit, V_{inH} is a value of the alternating-current component extracted by the alternating-current component extraction unit, a value V_{com} is given by (Vₚ+Vₙ)/2, and a value V_{dif} is given by (Vₚ−Vₙ)/2.

3. The motor drive device according to claim 1, wherein
the measurement resistor is connected between the connection point between the voltage dividing resistors and the positive potential line of the direct-current link, and
the insulation resistance value calculation unit calculates an insulation resistance value Rₘ of the motor in accordance with:
$$\begin{matrix}[ Math . 2 ] & \\ {R}_{m} = - \frac{{V}_{com} ( {V}_{dif} + {V}_{inL} )}{{V}_{inH} {V}_{dif}} {R}_{in} & \end{matrix}$$
where Rᵢₙ is a resistance value of the measurement resistor, Vₚ is a value of the positive potential measured by the direct-current link potential measurement unit, Vₙ is a value of the negative potential measured by the direct-current link potential measurement unit, V_{inL} is a value of the direct-current component extracted by the direct-current component extraction unit, V_{inH} is a value of the alternating-current component extracted by the alternating-current component extraction unit, a value V_{com} is given by (Vₚ+Vₙ)/2, and a value V_{dif} is given by (Vₚ−Vₙ)/2.

4. The motor drive device according to claim 1, wherein the voltage dividing resistors are respectively formed by two direct-current link resistors connected in series with each other between the positive potential line and the negative potential line of the direct-current link.

5. The motor drive device according to, claim 1, wherein the voltage dividing resistors are respectively formed by OFF resistors that occur upon turn-off of switching elements respectively provided in an upper arm and a lower arm forming a bridge circuit in the inverter unit.
